(19) United States
(12) Patent Application Publication
(10) Pub. No.: US 2016/0099409 A1
(43) Pub. Date: Apr. 7, 2016

(54) ULTRATHIN FILM RESISTIVE MEMORY DEVICES

(71) Applicant: The Trustees of the University of Pennsylvania, Philadelphia, PA (US)

(72) Inventors: I-Wei Chen, Swarthmore, PA (US); Jongho Lee, Philadelphia, PA (US)

(21) Appl. No.: 14/507,957

(22) Filed: Oct. 7, 2014

(51) Int. Cl. H01L 45/00; G11C 13/00

(52) U.S. Cl. CPC H01L 45/145; H01L 45/1233; H01L 45/1253; G11C 13/0021

(57) ABSTRACT

Provided are thin resistive devices and related methods, the devices featuring a resistance-switchable active layer having a thickness in the range of from about 1 to about 5 nm and an insulating layer surmounting the resistance-switchable active layer, the insulating layer having a thickness in the range of from about 0.5 nm to about 5 nm.

### TECHNICAL FIELD

The present disclosure relates to the field of resistive memory devices.

### BACKGROUND

Non-volatile resistance memory is a focus of memory research by the worldwide electronics industry, and is regarded as a promising candidate for future memory devices.

As there is an ongoing need for shrinking the size of electronic devices—in general the device thickness is commensurably shrunk along with the shrinking area—it is desirable to construct thinner devices that also meet users' performance demands.

In some instances, materials (also called dielectrics) that exhibit favorable insulating characteristics when in their bulk forms may nonetheless become conductors or “leaky insulators” when the materials are in a thin form. In the electronics industry, this is a well-known problem for gate oxides, which may have a thickness in the range of about 1 nm. Thus, the field faces an ongoing challenge in realizing thin electronic devices with a thickness of less than a few nanometers.

This is particularly true for non-volatile resistance switching devices that are required to maintain two resistance states: one is highly insulating having a high resistance value, i.e., it is a high resistance state (HRS); the other is highly conducting having a low resistance, i.e., it is a low resistance state (LRS). Further, these states must be able to maintain their respective resistance values when there is no voltage on the device and also maintain their values over long time periods, during which time the device may experience repeated probing of the state by a small voltage to verify the device's resistance. Devices may also face repeated switching between two states when memory is rewritten.

Given these demanding requirements, films of less than 5 nm thickness have not met the above needs. This is especially difficult in the case of so-called filamentary resistance-random-access-memory (RRAM), because switching in such devices is determined by a critical electric field. Because switching voltage is proportional to the thickness, the voltage can be very small in very thin films, making it very difficult to reliably control switching. Thus, there is a long-felt need in the art for comparatively thin devices that can meet the described performance criteria.

### SUMMARY

In meeting these challenges, provided here is a technology under which a thin (e.g., 2.5 nm) insulator-conductor mixture film (hereafter called active layer) may be made into a non-volatile resistance switching memory by adding a thin (e.g., 1-2 nm) interfacial layer (sometimes referred to as a “coat layer”) between the mixture film and a bottom electrode.

The coat layer can be made of any dielectric, e.g., aluminum oxide, hafnium oxide, titanium oxide and silicon nitride. The active layer can be made of any insulator-conductor mixture films known as nanometallic films, as are known in the art. Devices constructed with this technology exhibit excellent uniformity and endurance during repeated testing. The disclosed technology thus provides improved devices and related methods to utilize nanometallic films in a comparatively thin regime.

In one aspect, the present disclosure provides resistive devices, comprising: a resistance-switchable active layer having a thickness in the range of from about 1 to about 5 nm; and an insulating layer surmounting the resistance-switchable active layer, the insulating layer having a thickness in the range of from about 0.5 nm to about 5 nm.

The present disclosure also provides methods, comprising applying a voltage to a device so as to change a resistance state of the device, the device comprising a resistance-switchable active layer having a thickness in the range of from about 1 nm to about 5 nm, and an insulating layer surmounting the resistance-switchable active layer, the insulating layer having a thickness in the range of from about 0.5 nm to about 5 nm.

### BRIEF DESCRIPTION OF THE DRAWINGS

The summary, as well as the following detailed description, is further understood when read in conjunction with the appended drawings. For the purpose of illustrating the invention, there are shown in the drawings exemplary embodiments of the invention; however, the invention is not limited to the specific methods, compositions, and devices disclosed. In addition, the drawings are not necessarily drawn to scale. In the drawings:

FIG. 1 shows illustrative R-V curves of a 2.5 nm-thick SiN_{4/3}:Pt mixture film, with the combination of Mo and Pt electrodes.

FIG. 2 shows illustrative R-V curves of a 1 nm-thick ALD AlOₓ dielectric film, with Pt electrodes.

FIG. 3 shows illustrative R-V curves of one embodiment of the present invention using 1 nm-thick ALD AlOₓ coat layer and 2.5 nm-thick SiN_{4/3}:Pt active layer and with the combination of Mo and Pt electrodes.

FIG. 4 shows illustrative R-V curves of one embodiment of the present invention using 1 nm-thick ALD HfOₓ coat layer and 2.5 nm-thick SiN_{4/3}:Pt active layer and with the combination of Mo and Pt electrodes.

FIG. 5 shows illustrative R-V curves of one embodiment of the present invention using 1 nm-thick ALD TiOₓ coat layer and 2.5 nm-thick SiN_{4/3}:Pt active layer and with the combination of Mo and Pt electrodes.

FIG. 6 shows illustrative R-V curves of one embodiment of the present invention using sputter-deposited 2 nm-thick SiN_{4/3} coat layer and 2.5 nm-thick SiN_{4/3}:Pt active layer and with the combination of Mo and Pt electrodes. FIG. 7 shows cycling R-V curves of one embodiment of the present invention using 1 nm-thick ALD AlOₓ coat layer and 2.5 nm-thick SiN_{4/3}:Pt active layer and with the combination of Mo and Pt electrodes, tested with DC voltage cycled between −3 V and +4 V. Resistance checked using 0.2 V read voltage detected no noticeable degradation after 100 cycles. Switching voltages during cycling also show no noticeable change.

FIG. 8 shows a proposed, non-limiting principle of operation for the disclosed technology.

FIG. 9 shows four exemplary layer embodiments (top and bottom electrodes not shown; dielectric layers are denoted by I, and active layer denoted by S)—(a) I-S-I, (b) S-I-S, (b) I-S-I-S, and (d) I-S-I-S-I.

### DETAILED DESCRIPTION OF ILLUSTRATIVE EMBODIMENTS

The present invention can be understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention. Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

It is to be appreciated that certain features of the invention which are, for clarity, described herein in the context of separate embodiments, can also be provided in combination in a single embodiment. Conversely, various features of the invention that are, for brevity, described in the context of a single embodiment, can also be provided separately or in any subcombination. Further, reference to values stated in ranges includes each and every value within that range. Any documents cited herein are incorporated herein by reference in their entireties for any and all purposes.

In one aspect, the present disclosure provides electric (e.g., resistive) devices. The devices suitably comprise a resistance-switchable active layer having a thickness in the range of from about 0.5 nm to about 10 nm, or from about 1 nm to about 5 nm. The devices also suitably comprise an insulating layer surmounting the resistance-switchable active layer, the insulating layer having a thickness in the range of from about 0.5 nm to about 5 nm.

The devices may also include at least one electrode. An electrode is suitably in electronic communication with the resistance-switchable (active) layer, the insulating layer, or both. The electrode may—but need not—physically contact the active layer or the insulating layer.

Active layers, insulating layers, and other materials of the devices may be deposited by a variety of methods known to those of ordinary skill in the art. Atomic layer deposition (ALD) is one such method. Sputtering under a direct current or alternating current, with or without additional reactive species, is another such method.

An insulating layer suitably has a thickness in the range of from about 0.5 nm to about 5 nm, or from about 1 nm to about 3 nm, or even about 1 nm to about 2 nm. Insulating layers having a thickness of about 1 nm are considered especially suitable.

A variety of materials are suitable for the insulating layer, including oxides, nitrides, and oxynitrides. An insulating layer suitably comprises one or more oxides having the formula AOₓ, wherein A comprises Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, B, Al, Ga, In, Si, Ge, Sn, Pb, La, Ce, Pr, Nd, Pm, Sm, Eu, Gd, Tb, Dy, Ho, Er, Tm, Yb, Lu, or any combination thereof. The insulating layer may also comprise one or more nitrides having the formula ANₓ, wherein A comprises B, Al, Ga, In, C, Si, Ge, Sn, or any combination thereof.

An insulating layer may also comprise one or more oxynitrides having the formula AOₓN_{y}, wherein A comprises B, Al, Ga, In, C, Si, Ge, Sn, or any combination thereof. Insulating layer may also comprise one or more oxynitrides having the formula AOₓN_{y}M_{z}, wherein A comprises B, Al, Ga, In, C, Si, Ge, Sn, or any combination thereof, and M comprises Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Pb, La, Ce, Pr, Nd, Pm, Sm, Eu, Gd, Tb, Dy, Ho, Er, Tm, Yb, Lu, or any combination thereof.

An insulating layer may also include AlOₓ, SiOₓ, BOₓ, HfOₓ, ZrOₓ, TiOₓ, MgOₓ, YOₓ, ScOₓ, TaOₓ, SiNₓ, AlNₓ, SiOₓN_{y}, AlOₓN_{y} or any combination thereof.

In some embodiments, the insulating layer comprises a material having a bulk resistance in the range of from about 10⁸ ohm-m to about 10²⁵ ohm-m, or in the range of from about 10¹⁰ ohm-m to about 10²⁰ ohm-m, or in the range of from about 10¹² ohm-m to about 10²⁵ ohm-m.

Active layers may have a variety of configurations. In some embodiments, an active layer comprises (a) an electrically insulating composition and (b) an electrically conducting composition. Exemplary electrical conducting compositions include metals, e.g., Pt, Pd, Ni, W, Au, Ag, Cu, Al, Rh, Re, Ir, Os, Ru, Nb, Ti, Zr, Hf, V, Ta, Cr, Mo, Mn, Tc, Fe, Co, Zn, Cd, Hg, Ga, In, Tl, Sn, Pb, Sb, Bi, Be, Mg, Ca, Sr, Ba, Li, Na, K, Rb, Cs or any combination thereof. They may also include a conducting metal nitride, a conducting metal silicide, and combinations thereof. Insulating compositions include AlOₓN_{y}, (1-x-y-z)Si₃N₄-xAlN-yAl₂O₃zSiO₂, Si₃₋ₓAlₓN₄₋ₓOₓ, and any combination thereof. Suitable insulating compositions also include oxides AOₓ, wherein A comprises Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, B, Al, Ga, In, Si, Ge, Sn, Pb, La, Ce, Pr, Nd, Pm, Sm, Eu, Gd, Tb, Dy, Ho, Er, Tm, Yb, Lu, or any combination thereof. Switching layers may include an admixture of a conducting composition and an insulating composition. Suitable materials for switching layers known as nanometallics are provided in U.S. patent application Ser. No. 13/060,514 (“Non-Volatile Resistance-Switching Thin Film Devices,” filed Jul. 8, 2011) and also in international patent application PCT/US2013/030178 (“Non-Volatile Resistance-Switching Thin Film Devices,” filed Mar. 11, 2013), both of which are incorporated herein by reference in their entireties for any and all purposes.

In some embodiments, the active layer comprises an amorphous composition, an admixture of amorphous and crystalline composition, an admixture of amorphous composition and nanoparticles, and any combination thereof.

Devices according to the present disclosure may include electrodes. A device may inlcude a first electrode in electronic communication with the resistance-switchable layer and a second electrode in electronic communication with an insulating layer. The electrodes may be arranged such that the electrodes sandwich insulator and active layers disposed between the electrodes; such configurations are well-knownt to those of ordinary skill in the art.

A device according to the present disclosure may also include second, third, fourth, or additional insulating layers. Such layers suitably have a thickness in the range of from about 0.5 nm to about 5 nm, the resistance-switchable active layer being disposed between the first insulating layer and a first side of the second insulating layer. Suitable materials for insulating layers are described elsewhere herein, and are not repeated again for the sake of brevity. Insulating layers may differ from one another in terms of dimension, composition, or both.

A device may also include second, third, fourth, or additional resistance-switchable active layers. Such active layers suitably have a thickness in the range of from about 1 nm to about 5 nm, with an insulating layer being disposed between the first resistance-switchable active layer and a first side of a second resistance-switchable active layer in some embodiments. Suitable materials for resistance-switchable active layers are described elsewhere herein. Resistance-switchable active layers may differ from one another in terms of dimension, composition, or both.

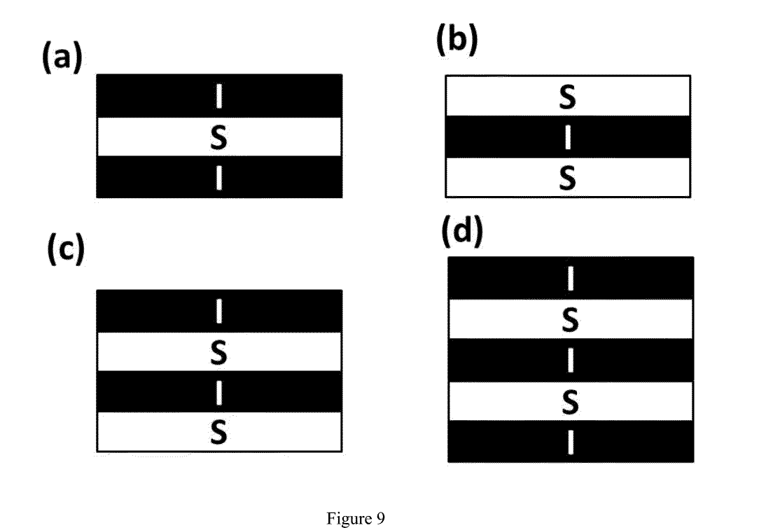

Devices according to the present disclosure may also comprise more than one insulating layer and more than one resistance-switchable active layer, as shown in FIG. 9. One or more of the insulating layers may contact two resistance-switchable active layers, or one or more of the resistance-switchable active layers may contact two insulating layers. Each of the insulating layer may have a thickness in the range from about 0.5 nm to 5 nm, and each of the resistance-switchable active layer may have a thickness in the range of from about 1 nm to about 5 nm.

Devices according to the present disclosure may have the layer configuration of insulating-active, or insulating-active-insulating, or active-insulating-active, or insulating-active-insulating-active, or insulating-active-insulating-active-insulating, and the like. As shown in FIG. 9 (in which dielectric layers are denoted by I, and active layer denoted by S), a device may be according to any of (a) I-S-I, (b) S-I-S, (b) I-S-I-S, or (d) I-S-I-S-I.

Devices according to the present disclosure may be of a variety of configurations. A device may be configured as a two-terminal memory device, or as a transistor, e.g., having multiple electrodes in contact with one or more resistance-switchable active layers, and with one or more insulating layers. Devices may also be configured as selectors, which selectors may regulate a memory device, e.g., a two-terminal resistance device.

The present disclosure also provides methods. These methods suitably include applying a voltage to a device (including devices according to the present disclosure) so as to change an electric (e.g., resistance) state of the device, the device comprising a resistance-switchable active layer having a thickness in the range of from about 1 nm to about 5 nm, and an insulating layer surmounting the resistance-switchable active layer, the insulating layer having a thickness in the range of from about 0.5 nm to about 5 nm.

A user of the disclosed methods may apply to the device a voltage in the range of from about 0.1 V to about 100 V, or from about 0.2 V to about 50 V, or from about 0.2 V to about 10 V, or from about 0.5 V to about 5 V. The voltage may be applied so as to affect a memory state (e.g., a resistance) of the device.

Suitable materials and dimensions of active layers and insulating layers are described elsewhere herein. According to the disclosed methods, the voltage may be applied by an electrode in electronic communication with the resistance-switchable active layer or the insulating layer. Suitable electrodes are described herein.

A device according to the present disclosure may have a cross-sectional dimension (e.g., thickness, width, length, height), in the range of about 2 to about 50 nm, from about 2 nm to about 100 nm, from about 2 nm to about 500 nm, from about 2 to about 1000 nm. A device may also have a cross-sectional dimension in the range of from about 1 micrometer to about 100 micrometers, from about 1 micrometer to about 500 micrometers, or even about 1 micrometer to about 1000 micrometers.

As described elsewhere herein, devices may further include a second insulating layer. Such layers may have a thickness in the range of from about 0.5 nm to about 5 nm, the resistance-switchable active layer being disposed between the first insulating layer and a first side of the the second insulating layer.

Also as described elsewhere herein, devices may further include a second resistance-switchable active layer. Such layers may have a thickness in the range of from about 1 nm to about 5 nm, the insulating layer being disposed between the first resistance-switchable layer and a first side of the second resistance-switchable layer.

Also as described elsewhere herein, devices may further include third and additional insulating layers, and third and additional active layers in some embodiments. As described above, a device may have the layer configuration of insulating-active, or insulating-active-insulating, or active-insulating-active, or insulating-active-insulating-active, or insulating-active-insulating-active-insulating, and the like.

### ADDITIONAL DISCLOSURE

Experimental evidence has shown that ultrathin films made of an insulating dielectric may be conductors or so-called leaky resistors. For example, 1 nm thick aluminum oxide films sandwiched between two platinum electrodes provide a comparatively small electrical resistance. Likewise, experiments have also verified that ultrathin nanometallic films made of an insulator-conductor mixture may be a conductor. For example, 2.5 nm thick SiN_{4/3}-Pt mixture films sandwiched between a platinum electrode and a molybdenum electrode provide only a very small electrical resistance.

Surprisingly, however, when a 1 nm aluminum oxide film is coated onto the 2.5 nm SiN_{4/3}-Pt mixture films, and with the bilayer film sandwiched between a platinum electrode and a molybdenum electrode, one may obtain an excellent RRAM with highly reproducible, uniform and durable resistance switching behavior. This unexpected discovery can be applied to electonic devices in general, in particulate to constructing high quality RRAM of ultrathin thickness.

By stacking a comparatively thin resistance-switching active layer with an ultrathin dielectric coat layer, thin and reliable resistance-switching devices can be constructed. This technology is particularly applicable to nanometallic films used as active layers, as the switching voltage of such films has little thickness dependency. Thus, reliable switching and reading of the ultrathin RRAM is possible at the same voltage regardless of device thickness, which in turn greatly simplifies device designs.

### Non-Limiting Examples

### Example A (Ultrathin Devices Enabled by Inserting a Coat Layer)

An ultrathin resistance switching memory is demonstrated by the following combination of materials. The substrate is a single crystal silicon wafer with p-type or n-type conductivity and is covered by thermal oxide to passivate bottom electrode from potential leakage current through silicon. The bottom electrode is Mo with a thickness of ˜10 nm. The active layer is a mixture of insulator and conductor composition, namely Si₃N₄ and Pt, respectively. The coat layer is Al₂O₃ (i.e., AlOₓ given the possibility of non-stoichiometry; in the following Al₂O₃ and AlOₓ will be used interchangeably) with a thickness of 1 nm. The top electrode is a patterned Pt with a thickness of ˜40 nm. The device size is defined by the patterned size of Pt, which varies from 10 μm to 260 μm.

In the above, the bottom electrode can be any metal of suitable resistance. Other than Mo, Ti is also a suitable choice, as are many other metals. There are also many choices for top electrodes. Pt is particularly suitable because of its mechanical stability and resistance to scratch, oxidation and corrosion by chemicals. These electrodes can be deposited by DC or RF sputtering, or by any other suitable techniques such as thermal or electron-beam evaporation. The active layer is an amorphous mixture of insulator and conductor, which again have many choices. It can be suitably deposited by RF-cosputtering using separate targets, one for insulator such as Si₃N₄, the other for conductor such as Pt, as in this example, but other methods of forming a thin layer is also suitable.

The coat layer is an insulator, such as Al₂O₃, for which a uniform 1 nm thin film can be deposited using such technique as atomic layer deposition (ALD), but any other suitable deposition methods such as chemical vapor deposition (CVD), sputtering and evaporation or physical vapor deposition (PVD) can also be used. In this example, an ALD process was used with a substrate temperature of 150° C., with 12 cycles of AlOₓ layer formation when a metal precursor and an oxygen source (water vapor) were provided.

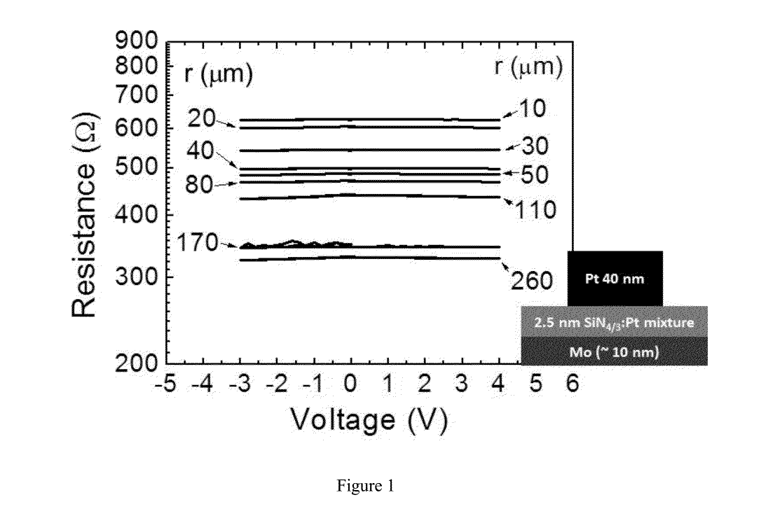

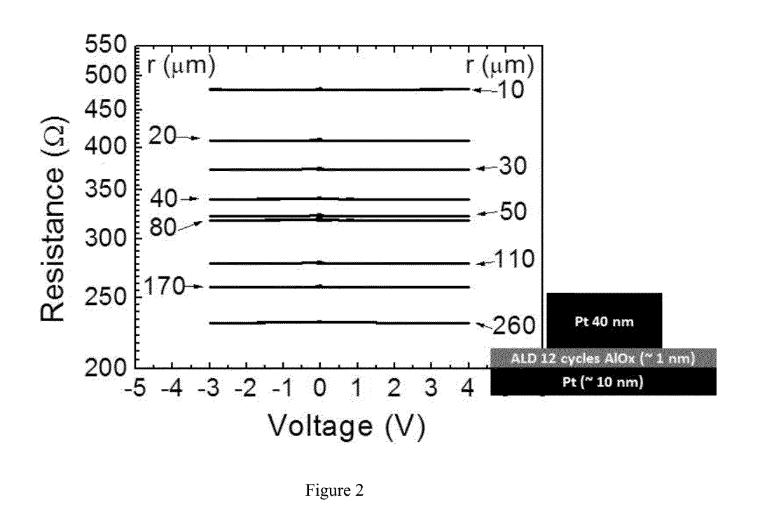

When the thickness of active layer or coat layer is individually reduced to become ultrathin, then each layer becomes conducting. FIG. 1 shows resistance-voltage (R-V) characteristics of a 2.5 nm-thick SiN_{4/3}:Pt active layer, between a Mo bottom electrode and a Pt top electrode of various sizes. Likewise, FIG. 2 shows R-V curves of an approximately 1 nm-thick ALD-deposited AlOₓ thin film, between Pt electrodes of various sizes. Both FIG. 1 and FIG. 2 feature flat R-V curves of relatively low resistance values less than 1 kΩ that are nearly voltage independent. Little to no resistance hysteresis indicating resistance switching is apparent in FIG. 1.

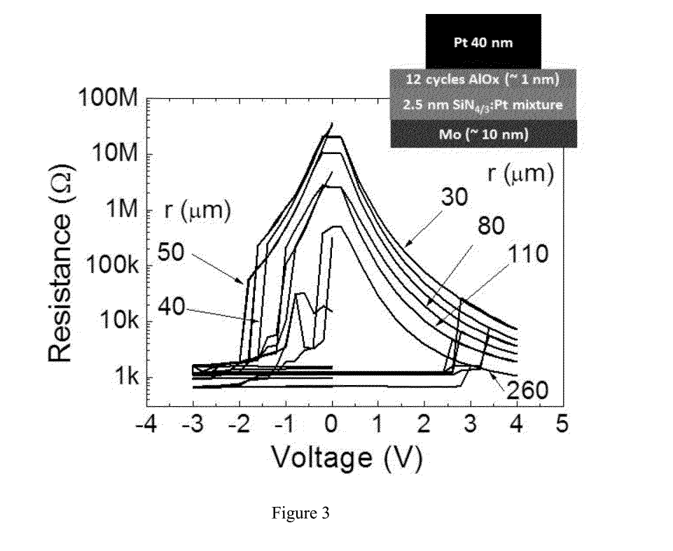

By contrast, in the disclosed devices having the combination of an active layer and a coat layer of the above types, the combined stack shows a prominent R-V hysteresis indicating distinct resistance switching and non-volatile resistance values at zero voltage, as illustrated in FIG. 3. In this example, the voltage sweep starts from 0 V, then decreases to −3 V, then increases to 4 V, and finally returns to 0 V. Between −1 and −2 V, there is typically one sharp transition of resistance drop followed by several other smaller or continuous drops of resistance; this is ON switching and the device is turned to the low resistance state (LRS).

As illustrated in FIG. 3, when voltage reaches 2.5˜3.5 V, there is a sudden rise of resistance and the R-V curve changes the trajectory from flat (for the LRS) to exponentially varying, which is characteristic of the high resistance state (HRS); this is OFF switching as the device is turned to the HRS. Without a voltage, these devices can still maintain its respective resistance states of HRS or LRS. Thus, the devices may be used as non-volatile resistance memory.

Electric characteristics above were examined using a Keithley 237 DC power source and a Signatone 5-1160 probe station. Current-voltage (I-V) and resistance-voltage (R-V) curves were measured in continuous voltage-sweep modes. The resistance is defined as the ratio of V/I. As used in the following tests, positive bias is the one causing a current to flow from the top electrode to the bottom electrode. X-ray diffraction by theta-2 theta diffractometer and plan-view transmission electron microscopy were used to analyze microstructure. The active layer is amorphous according to X-ray diffraction and transmission microscopy without any evidence of a crystalline phase. This indicates that the existence of metal nanoparticles is not essential for the observed resistance switching in the above combined stack.

### Example B (Coat Layer)

Another embodiment of the present ultrathin resistance switching memory is demonstrated by the following combination of materials. The substrate is a single crystal silicon wafer with p-type or n-type conductivity and is covered by thermal oxide. The bottom electrode is Mo with a thickness of ˜10 nm. The active layer is a mixture of insulator and conductor, namely Si₃N₄ and Pt, of 2.5 nm.

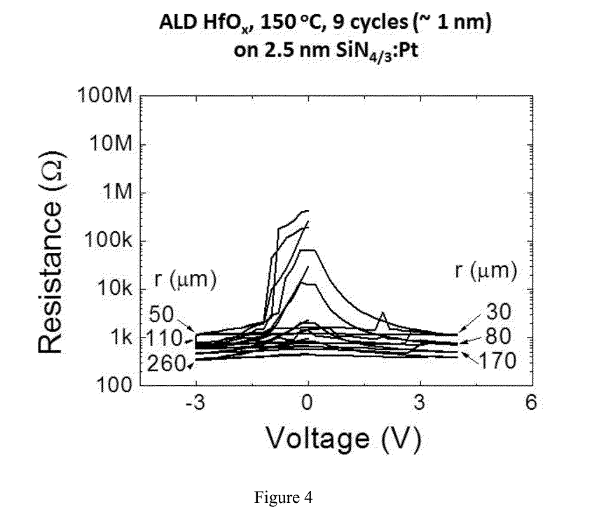

The coat layer is HfOₓ, which is herein used interchangeably with HfO₂, with a thickness of 1 nm deposited by ALD at 150° C. using 9 cycles. The top electrode is a patterned Pt with a thickness of ˜40 nm of various sizes. The device size is defined by the patterned size of Pt, which varies from 30 μm to 260 μm. The combined stack shows a prominent R-V hysteresis indicating distinct resistance switching and non-volatile resistance values at zero voltage, as illustrated in FIG. 4.

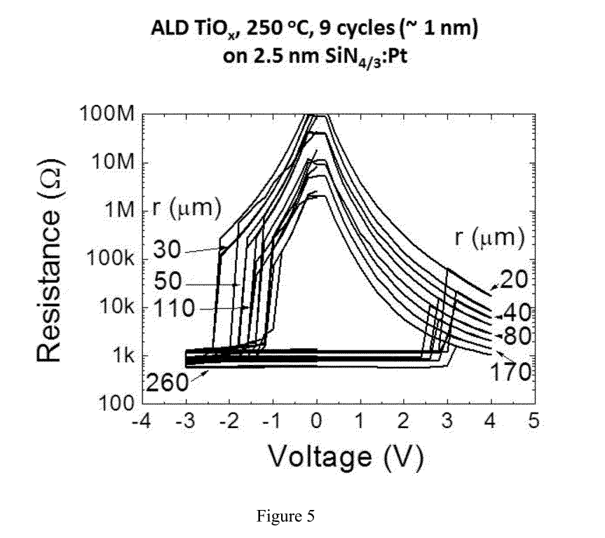

Another embodiment of the present ultrathin resistance switching memory is demonstrated by using the same substrate, electrodes, and active layer, but replacing the coat layer by TiOₓ, which is herein used interchangeably with TiO₂,. Here, the coat layer has a thickness of ˜1 nm and was deposited by ALD at 250° C. using 9 cycles. The device size varies from 20 μm to 260 μm. The combined stack shows R-V hysteresis indicating distinct resistance switching and non-volatile resistance values at zero voltage, as illustrated in FIG. 5.

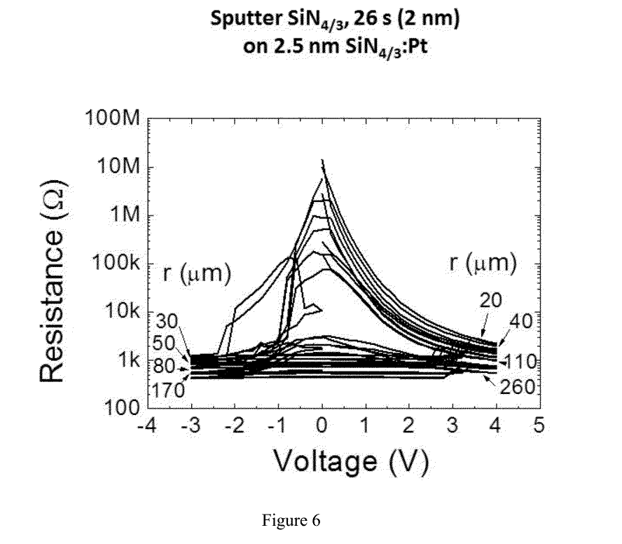

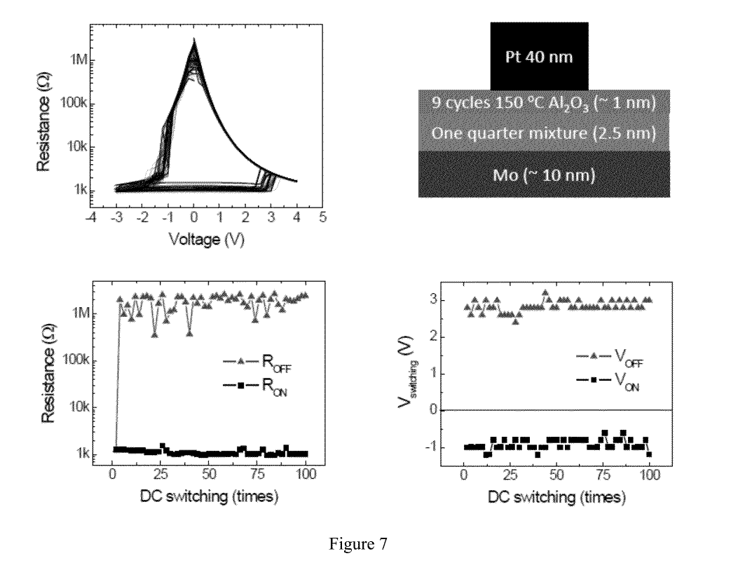

Another embodiment of the present ultrathin resistance switching memory is demonstrated by using the same substrate, electrodes, and active layer, but replacing the coat layer by Si₃N₄, which is herein used interchangeably with SiN_{4/3},. Here, the coat layer has a thickness of ˜2 nm and was deposited by RF-magnetron sputtering at room temperature using a Si₃N₄ target in 26 seconds. The device size varies from 20 μm to 260 μm. The combined stack shows a prominent R-V hysteresis indicating distinct resistance switching and non-volatile resistance values at zero voltage, as illustrated in FIG. 6.

### Example C (Reliability, Uniformity, and Retention)

Reliability and uniformity is valued for high quality memory devices, as such devices must allow precise reading of the memory state using a preset read voltage. Minimum changes in resistance values are desired since a memory must be read and written many times. In this example, a read voltage of 0.2 V is used, and the write cycle is the same as the voltage sweep cycles, from −3 V to +4 V, used in Example A. Degradation by repeated testing is indicated by a systematic variation of resistance values or inability to switch when the device is stuck to either the HRS or the LRS. The present ultrathin devices show excellent uniformity and reliability without any indication of degradation in cyclic testing. FIG. 7 displays 100 consecutive resistance switching R-V curves, which tightly coincide with each other featuring similar ON/OFF switching voltages and nearly constant ON/OFF resistance values. The OFF resistance is 1.79±0.62 MΩ, the ON resistance is 1.11±0.13 kΩ, the OFF voltage is 2.83±0.15 V, and the ON voltage is −0.92±0.14 V, demonstrating excellent reproducibility and absence of degradation.

When the ultrathin devices are kept without voltage or power over one week and then retested, they showed no lapse of memory, i.e., the memory state stayed at the respective HRS or LRS as previously set/reset. Thus, these ultrathin memory devices have been shown to be non-volatile, reliable, and have good retention characteristics.

### Suggested Principle of Operation

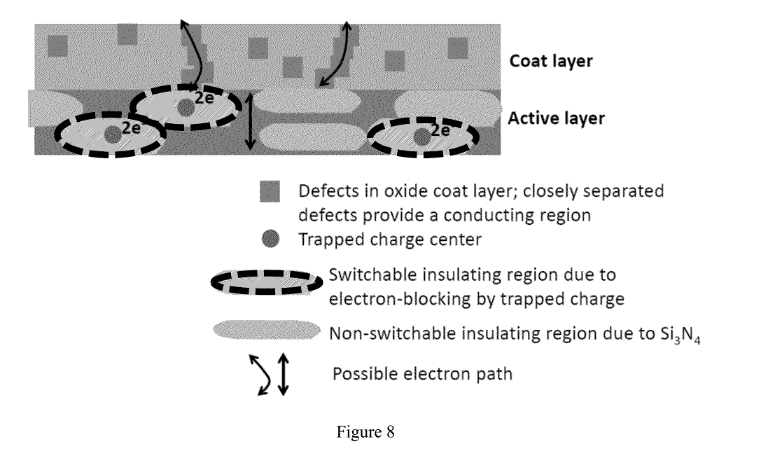

Without being bound by any particular theory, FIG. 8 is provided to explain the role of the coat layer. As shown in FIG. 8, both the coat layer and the active layers may be modeled as containing defects.

In the coat layer, such defects when in close separation create minority regions of the conducting type, surrounded by uniformly distributed majority regions of the insulating type. In the active layer, such defects, which contain trapped electrons, block conduction, creating minority regions of the insulating type, surrounded by uniformly distributed majority regions of both the insulating type and the conducting type.

The conducting minority regions in the coat layer are short-ranged in spatial extent. Therefore, thick films of coat layers are insulators, as is well known for Al₂O₃, HfOₓ, TiOₓ, and Si₃N₄. Likewise, the conducting paths in the active layer, being tortuous and often blocked by the insulating regions, is also short-ranged, so thick films of Si₃N₄:Pt are insulators, as is also known when the Pt:Si ratio is less than 0.4.

However, thin films of active layer and coat layer are both conductors since conducting paths of a short-range nature are available, which is experimentally verified in FIG. 1 and FIG. 2, respectively. On the other hand, stacking the two layers together may be thought of as effectively increasing the film thickness, preventing the overlap of minority conducting regions of the two layers at their interface, resulting in no conducting path across the stack at all. This is the high resistance state or HRS.

When a critical switching voltage is applied, the defect-associated non-conducting regions in the active layer will turn conducting, as the trapped charge is driven off by the voltage and the blockade is removed. This allows conduction across the combined stack to establish along some paths that follow the overlap of the minority conducting regions in the coat layer and the defect-associated regions—now conducting as enabled by the critical voltage, which is the low resistance state or LRS. At an opposite critical switching voltage, the trapped charge is replenished, and the defect-associated non-conducting regions in the active layer return, thus causing resistance switching to the HRS.

Advantageously, this invention finds the critical switching voltages, shown in FIG. 3-7, are identical or similar to what have been observed in the active layer of an intermediate thickness, e.g., from about 4 to 30 nm, which is known to be an excellent non-volatile resistance switching memory itself This allows memory devices to be fabricated with any thickness desired, ranging from, e.g., 0.5 nm to 30 nm, with the same sets of critical switching voltages and read voltages.

What is claimed:

1. A resistive device, comprising:
a resistance-switchable active layer having a thickness in the range of from about 1 to about 5 nm; and
an insulating layer surmounting the resistance-switchable active layer, the insulating layer having a thickness in the range of from about 0.5 nm to about 5 nm.

2. The resistive device of claim 1, further comprising an electrode in electronic communication with the resistance-switchable layer, the insulating layer, or both.

3. The resistive device of claim 1, wherein the insulating layer has a thickness in the range of from about 1 nm to about 3 nm.

4. The resistive device of claim 1, wherein the insulating layer comprises an oxide, nitride or oxynitride.

5. The resistive device of claim 4, wherein the insulating layer comprises (1) one or more oxides having the formula AOₓ, wherein A comprises Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, B, Al, Ga, In, Si, Ge, Sn, Pb, La, Ce, Pr, Nd, Pm, Sm, Eu, Gd, Tb, Dy, Ho, Er, Tm, Yb, Lu, or any combination thereof; (2) one or more nitrides having the formula ANₓ, wherein A comprises B, Al, Ga, In, C, Si, Ge, Sn, or any combination thereof; (3) one or more oxynitrides having the formula AOₓN_{y}, wherein A comprises B, Al, Ga, In, C, Si, Ge, Sn, or any combination thereof; or (4) one or more oxynitrides having the formula AOₓN_{y}M_{z}, wherein A comprises B, Al, Ga, In, C, Si, Ge, Sn, or any combination thereof, and M comprises Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Pb, La, Ce, Pr, Nd, Pm, Sm, Eu, Gd, Tb, Dy, Ho, Er, Tm, Yb, Lu, or any combination thereof.

6. The resistive device of claim 1, wherein the insulating layer comprises a material having a bulk resistance in the range of about 10⁸ ohm-m to about 10²⁵ ohm-m.

7. The resistive device of claim 1, wherein the insulating layer comprises AlOₓ, SiOₓ, BOₓ, HfOₓ, ZrOₓ, TiOₓ, MgOₓ, YOₓ, ScOₓ, TaOₓ, SiNₓ, AlNₓ, SiOₓN_{y}, AlOₓN_{y} or any combination thereof.

8. The resistive device of claim 1, wherein the active layer comprises (a) an electrically insulating composition and (b) an electrically conducting composition.

9. The resistive device of claim 8, wherein the electrical conducting composition comprises a metal M, wherein M comprises Pt, Pd, Ni, W, Au, Ag, Cu, Al, Rh, Re, Ir, Os, Ru, Nb, Ti, Zr, Hf, V, Ta, Cr, Mo, Mn, Tc, Fe, Co, Zn, Cd, Hg, Ga, In, Tl, Sn, Pb, Sb, Bi, Be, Mg, Ca, Sr, Ba, Li, Na, K, Rb, Cs or any combination thereof.

10. The resistive device of claim 2, wherein the electrode physically contacts the resistance-switchable active layer or the insulating layer.

11. The resistive device of claim 1, further comprising a first electrode in electronic communication with the resistance-switchable layer and a second electrode in electronic communication with the insulating layer.

12. The resistive device of claim 1, wherein the device is configured as a memory device.

13. The resistive device of claim 1, further comprising a second insulating layer having a thickness in the range of from about 0.5 nm to about 5 nm, the resistance-switchable active layer being disposed between the first insulating layer and a first side of the second insulating layer.

14. The resistive device of claim 13, further comprising a second resistance-switchable active layer, the second resistance-switchable active layer contacting the second side of the second insulating layer.

15. The resistive device of claim 14, the second resistance-switchable active layer having a thickness in the range of from about 1 nm to about 5 nm.

16. The resistive device of claim 14, further comprising a third insulating layer having a thickness in the range of from about 0.5 nm to about 5 nm, the second resistance-switchable active layer being disposed between the second insulating layer and the third insulating layer.

17. The resistive device of claim 1, further comprising a second resistance-switching layer having a thickness in the range of from about 1 nm to about 5 nm, the insulating layer being disposed between the first resistance-switching layer and a first side of the second resistance-switching layer.

18. A method, comprising:
applying a voltage to a device so as to change a resistance state of the device,
the device comprising a resistance-switchable active layer having a thickness in the range of from about 1 nm to about 5 nm, and
an insulating layer surmounting the resistance-switchable active layer, the insulating layer having a thickness in the range of from about 0.5 nm to about 5 nm.

19. The method of claim 18, wherein the voltage is in the range of from about 0.2 V to about 10 V.

20. The method of claim 18, wherein the voltage is effected so as to affect a memory state of the device.

21. The method of claim 18, wherein the insulating layer has a thickness in the range of from about 1 nm to about 3 nm.

22. The method of claim 18, wherein the insulating layer comprises an oxide, nitride or oxynitride.

23. The method of claim 18, wherein the insulating layer comprises (1) one or more oxides having the formula AOₓ, wherein A comprises Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, B, Al, Ga, In, Si, Ge, Sn, Pb, La, Ce, Pr, Nd, Pm, Sm, Eu, Gd, Tb, Dy, Ho, Er, Tm, Yb, Lu, or any combination thereof; (2) one or more nitrides having the formula ANₓ, wherein A comprises B, Al, Ga, In, C, Si, Ge, Sn, or any combination thereof; (3) one or more oxynitrides having the formula AOₓN_{y}, wherein A comprises B, Al, Ga, In, C, Si, Ge, Sn, or any combination thereof; or (4) one or more oxynitrides having the formula AOₓN_{y}M_{z}, wherein A comprises B, Al, Ga, In, C, Si, Ge, Sn, or any combination thereof, and M comprises Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Pb, La, Ce, Pr, Nd, Pm, Sm, Eu, Gd, Tb, Dy, Ho, Er, Tm, Yb, Lu, or any combination thereof.

24. The method of claim 18, wherein the insulating layer comprises a material having a bulk resistance in the range of about 10⁸ ohm-m to about 10²⁵ ohm-m.

25. The method of claim 18, wherein the active layer comprises (a) an electrically insulating composition; and (b) an electrically conducting composition.

26. The method of claim 25, wherein the conductive composition comprises a metal M, wherein M comprises Pt, Pd, Ni, W, Au, Ag, Cu, Al, Rh, Re, Ir, Os, Ru, Nb, Ti, Zr, Hf, V, Ta, Cr, Mo, Mn, Tc, Fe, Co, Zn, Cd, Hg, Ga, In, Tl, Sn, Pb, Sb, Bi, Be, Mg, Ca, Sr, Ba, Li, Na, K, Rb, Cs or any combination thereof.

27. The method of claim 18, wherein the voltage is applied by an electrode in electronic communication with the resistance-switchable active layer or the insulating layer.

28. The method of claim 18, wherein the device further comprises a second insulating layer having a thickness in the range of from about 0.5 nm to about 5 nm, the resistance-switchable active layer being disposed between the first insulating layer and a first side of the second insulating layer.

29. The resistive device of claim 28, wherein the device further comprises a second resistance-switchable active layer, the second resistance-switchable active layer contacting the second side of the second insulating layer.

30. The resistive device of claim 28, wherein the second resistance-switchable active layer has a thickness in the range of from about 1 nm to about 5 nm.

31. The resistive device of claim 28, wherein the device further comprises a third insulating layer having a thickness in the range of from about 0.5 nm to about 5 nm, the second resistance-switchable active layer being disposed between the second insulating layer and the third insulating layer.

32. The method of claim 18, wherein the device further comprises a second resistance-switching layer having a thickness in the range of from about 1 nm to about 5 nm, the insulating layer being disposed between the first resistance-switching layer and a first side of the second resistance-switching layer.
